(19) United States
(12) Patent Application Publication
(10) Pub. No.: US 2022/0085255 A1
(43) Pub. Date: Mar. 17, 2022

(54) WHITE LIGHT EMITTING DIODE AND BACKLIGHT MODULE AND DISPLAY DEVICE COMPRISING THE SAME

(71) Applicants: Chung-Hwa LEE, New Taipei City (TW); Jian-Ging CHEN, Kaohsiung City (TW)

(72) Inventors: Chung-Hwa LEE, New Taipei City (TW); Jian-Ging CHEN, Kaohsiung City (TW)

(21) Appl. No.: 17/472,752

(22) Filed: Sep. 13, 2021

(30) Foreign Application Priority Data
Sep. 14, 2020 (TW) 109131430

(51) Int. Cl. H01L 33/50; H01L 33/60; H01L 33/52; G02F 1/13357

(52) U.S. Cl. CPC H01L 33/504; G02F 1/133603; H01L 33/52; H01L 33/60

(57) ABSTRACT

A white light emitting diode is disclosed, which comprises: a blue light emitting diode chip; a phosphor layer disposed on the blue light emitting diode chip; and a light absorbing material disposed on the phosphor layer or in the phosphor layer, wherein the light absorbing material is a yellow light absorbing material. In addition, a backlight module and a display device using the aforesaid white light emitting diode are also disclosed.

### CROSS REFERENCE TO RELATED APPLICATION

This application claims the benefits of the Taiwan Patent Application Serial Number 109131430, filed on Sep. 14, 2020, the subject matter of which is incorporated herein by reference.

### BACKGROUND

### 1. Field

The present disclosure relates to a white light emitting diode, and a backlight module and a display device comprising the same. More specifically, the present disclosure relates to a white light emitting diode with improved color gamut, and a backlight module and a display device comprising the same.

### 2. Description of Related Art

White light emitting diodes can be applied to various fields, and for example, can be applied to light sources or backlight modules of display devices. The material of the light emitting layer of the white light emitting diodes know in the art can be phosphors or quantum dots. However, compared to the light emitting from quantum dots, the light emitting from the phosphors comprises the light with undesired wavelengths. Thus, the color gamut of the white light emitting diodes prepared with the phosphors is not ideal. Currently, some manufactures prepare white light emitting diodes with quantum dots as the materials of the light emitting layers to improve the backlight effect of the backlight module used in the display device.

However, the manufacturing cost of the quantum dots is high. If the color gamut of the white light emitting diode can be improved by effectively removing the light with the undesired wavelengths, the backlight effect of the backlight module in the display device may further be improved even though the quantum dots are not used as the material of the light emitting layer in the white light emitting diode.

Therefore, it is desirable to develop a novel white light emitting diode using phosphors, which can be used in the backlight module of the display device.

### SUMMARY

The present disclosure provides a white light emitting diode, and the color gamut of the white light emitting diode can be improved by using a yellow light absorbing material.

The white light emitting diode of the present disclosure comprises: a blue light emitting diode chip; a phosphor layer disposed on the blue light emitting diode chip; and a light absorbing material disposed on the phosphor layer or in the phosphor layer, wherein the light absorbing material is a yellow light absorbing material.

In the white light emitting diode of the present disclosure, the light with undesired wavelength in the yellow light wavelength range can be absorbed by using the yellow light absorbing material. Thus, the intensity of the light with undesired wavelength can be reduced to increase the color gamut of the white light emitting diode. Thus, when the white light emitting diode of the present disclosure is applied to the backlight module of the display device, the backlight with wide color gamut can be provided, and the display quality of the display device can further be improved.

In the white light emitting diode of the present disclosure, the blue light emitting diode chip may be a blue light epitaxial chip formed with an epitaxial layer, a face-up chip, a vertical chip or a flip chip.

In the white light emitting diode of the present disclosure, the yellow light absorbing material may be a material capable of absorbing light having wavelength ranged from 550 nm to 610 nm Herein, the types of the yellow light absorbing material are not particularly limited, as long as it is a material capable of absorbing light having the aforesaid wavelength range. The yellow light absorbing material may be an organic dye or an inorganic dye. The examples of the yellow light absorbing material may comprise, but are not limited to triphenylmethane-based material, cobalt blue, cobalt violet or a combination thereof.

In the white light emitting diode of the present disclosure, the phosphor layer may a phosphor gel layer, which may be a layer formed by a gel containing phosphor particles.

In the white light emitting diode of the present disclosure, the phosphor layer may be a thin film of phosphors, which may be a thin film constituted by phosphor particles. When the phosphor layer is the thin film of phosphors, the white light emitting diode of the present disclosure may further comprise a protection layer disposed on the thin film of the phosphors, and the light absorbing material is disposed on the protection layer.

In the white light emitting diode of the present disclosure, the types of the phosphor particles containing in the phosphor layer are not particularly limited, and may be selected according to the types of the light emitting diode chip or the color of the light emitting from the phosphor particles. For example, the phosphor particles may be the phosphor particles capable of emitting yellow light after excitation. When the blue light emitting diode chip is used with the phosphor particles capable of emitting yellow light after excitation, the light emitting diode of the present disclosure can emit white light.

In the present disclosure, examples of the phosphors may comprise, but are not limited to, potassium fluorosilicate, beta-Sialon, ZnO, ZrO₂, PbO, Y₂O₃, Y₂O₂, Zn₂SiO₄, Y₃Al₅O₁₂, Y₃(AlGa)₅O₁₂Y₂SiO₅, LaOCl, InBO₃, ZnGa₂O₄, ZnS, PbS, CdS, CaS, SrS, ZnₓCd₁₋ₓS, Y₂O₂S, AlN or Gd₂O₂S. In addition, the compounds for forming the phosphors may be selectively further doped with at least one element selected from the group consisting of Cu, Ag, Eu, Yb, La, Cl, Tb, Al, Ce, Er, Zn, Mn and other lanthanides (such as Pr, Pm, Sm, Ho, or Er). However, the present disclosure is not limited thereto.

In one embodiment of the present disclosure, the particle size of the phosphors may be ranged from 10 nm to 5000 nm. In another embodiment of the present disclosure, the particle size of the phosphors may be ranged from 10 nm to 100 nm. In further another embodiment of the present disclosure, the particle size of the phosphors may be ranged from 10 nm to 30 nm. However, the present disclosure is not limited thereto.

In the white light emitting diode of the present disclosure, the material of the protection layer may comprise, but is not limited to, SiO₂, Al₂O₃, ZnO, ZrO, Y₂O₃, TiO₂, CoO, MnO₂, NiO, CuO, PbO, optical gel or a combination thereof.

In addition, the present disclosure further provides a backlight module, which comprises: a reflecting film; an optical film disposed on the reflecting film; and the aforesaid white light emitting diode disposed between the reflecting film and the optical film. Furthermore, the present disclosure further provides a display device, which comprises: the aforesaid backlight module; and a display panel disposed on the backlight module.

In the present disclosure, the backlight module can be a direct-light type backlight module or an edge-light type backlight module based on the disposition position of the white light emitting diode.

In the present disclosure, the display panel can be a display panel requiring a backlight source. For example, the display panel can be a liquid crystal display panel.

In the backlight module and the display device of the present disclosure, the color gamut of the backlight module can be improved by using the aforesaid white light emitting diode. Thus, even though the phosphor layer is used as the light emitting layer in the white light emitting diode of the present disclosure, the backlight effect of the backlight module using the white light emitting diode can be similar to the backlight effect of the backlight module using the light emitting diode using quantum dots in the light emitting layer.

Other novel features of the disclosure will become more apparent from the following detailed description when taken in conjunction with the accompanying drawings.

### BRIEF DESCRIPTION OF THE DRAWINGS

FIG. 1 is a cross-sectional view of a white light emitting diode according to Embodiment 1 of the present disclosure.

FIG. 2A to FIG. 2D are cross-sectional views showing a process for manufacturing a white light emitting diode according to Embodiment 2 of the present disclosure.

FIG. 3 is a cross-sectional view of a white light emitting diode according to Embodiment 3 of the present disclosure.

FIG. 4 is a cross-sectional view of a white light emitting diode according to Embodiment 4 of the present disclosure.

FIG. 5 is a cross-sectional view of a direct-light type backlight module according to Embodiment 5 of the present disclosure.

FIG. 6 is a cross-sectional view of an edge-light type backlight module according to Embodiment 6 of the present disclosure.

FIG. 7 is a cross-sectional view of a display device according to Embodiment 7 of the present disclosure.

FIG. 8 is a cross-sectional view of a testing unit used in Test example of the present disclosure.

FIG. 9A and FIG. 9B are respectively a diagram showing a testing results of a comparative example and an experimental example according to Test example of the present disclosure.

### DETAILED DESCRIPTION OF EMBODIMENT

The following embodiments when read with the accompanying drawings are made to clearly exhibit the above-mentioned and other technical contents, features and/or effects of the present disclosure. Through the exposition by means of the specific embodiments, people would further understand the technical means and effects the present disclosure adopts to achieve the above-indicated objectives. Moreover, as the contents disclosed herein should be readily understood and can be implemented by a person skilled in the art, all equivalent changes or modifications which do not depart from the concept of the present disclosure should be encompassed by the appended claims.

Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

Furthermore, the terms recited in the specification and the claims such as “above”, “over”, or “on” are intended not only directly contact with the other element, but also intended indirectly contact with the other element. Similarly, the terms recited in the specification and the claims such as “below”, or “under” are intended not only directly contact with the other element but also intended indirectly contact with the other element.

In addition, the features in different embodiments of the present disclosure can be mixed to form another embodiment.

### Embodiment 1

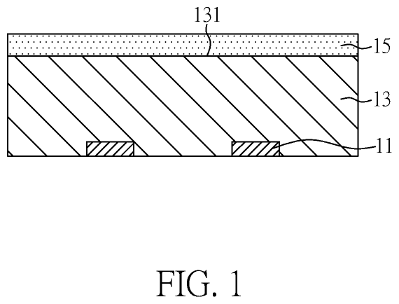

FIG. 1 is a cross-sectional view of a white light emitting diode according to the present embodiment. First, a blue light emitting diode chip 11 is provided, and a phosphor layer 13 is formed on the blue light emitting diode chip 11. In the present embodiment, the phosphor layer 13 is a phosphor gel layer. Then, a light absorbing material 15 is applied onto the light emitting surface 131 of the phosphor layer 13 to obtain the white light emitting diode of the present embodiment.

Herein, the forming method of the light absorbing material 15 is not particularly limited, and the light absorbing material 15 can be formed by any coating process known in the art. For example, the light absorbing material 15 can be formed by spin coating, blade coating, inkjet coating, printing, roll coating, spray coating, etc. In the present embodiment, the light absorbing material 15 is applied onto the light emitting surface 131 of the phosphor layer 13 through the inkjet coating.

As shown in FIG. 1, the white light emitting diode of the present embodiment comprises: a blue light emitting diode chip 11; a phosphor layer 13 disposed on the blue light emitting diode chip 11; and a light absorbing material 15 disposed on the phosphor layer 13, wherein the light absorbing material 15 is a yellow light absorbing material.

In the present embodiment, the phosphor layer 13 is a phosphor gel layer, which can be a layer formed by a gel containing phosphor particles. In the present embodiment, the blue light emitting diode chip 11 can emit blue light, and the phosphor particles contained in the phosphor layer 13 are the phosphor particles capable of emitting yellow light. The blue light emitting from the blue light emitting diode chip 11 can mix with the yellow light emitting from the phosphor particles contained in the phosphor layer 13 to obtain the white light.

Even though the blue light emitting from the blue light emitting diode chip 11 can mix with the yellow light emitting from the phosphor particles contained in the phosphor layer 13 to obtain the white light, the light absorbing material 15 is further used in the white light emitting diode of the present embodiment to absorb the light with undesired wavelength in the yellow light wavelength range, and to further improve the color gamut of the white light emitting diode. In the present embodiment, the light absorbing material 15 is formed in a thin film on the light emitting surface 131 of the phosphor layer 13. Herein, the light absorbing material 15 is a yellow light absorbing material capable of absorbing light having wavelength ranged from 550 nm to 610 nm. Herein, the examples of the yellow light absorbing material capable of absorbing light having wavelength ranged from 550 nm to 610 nm may comprise, but are not limited to triphenylmethane-based material, cobalt blue, cobalt violet or a combination thereof.

Hence, in the white light emitting diode of the present embodiment, by forming the light absorbing material 15 on the light emitting surface 131 of the phosphor layer 13, the light emitting from the phosphor layer 13 may pass through the light absorbing material 15, and the light absorbing material 15 can absorb the undesired yellow light to improve the color gamut of the white light emitting diode.

### Embodiment 2

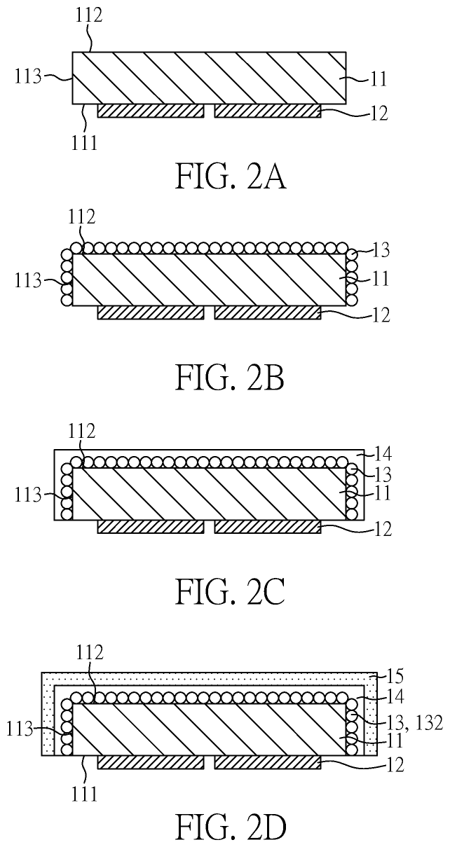

FIG. 2A to FIG. 2B are cross-sectional views showing a process for manufacturing a white light emitting diode of the present embodiment.

As shown in FIG. 2A, a blue light emitting diode chip 11 is provided, which has a first surface 111 and a second surface 112 opposite to the first surface 111, and two electrodes 12 (respectively a cathode and an anode) are disposed on the first surface 111 of the blue light emitting diode chip 11. In addition, the blue light emitting diode chip 11 further include a side surface 113 connecting to the first surface 111 and the second surface 112. In the present embodiment, the blue light emitting diode chip 11 is a blue light flip chip. In particular, the blue light emitting diode chip 11 is a blue light flip chip with an epitaxial layer formed thereon.

As shown in FIG. 2B, a phosphor layer 13 is formed on the second surface 112 and the side surface 113 of the blue light emitting diode chip 11. In the present embodiment, the method for forming the phosphor layer 13 is not particularly limited and may be formed by the method illustrated in Taiwan Patent Number 1398306.

As shown in FIG. 2C, a protection layer 14 is formed on the phosphor layer 13. In the present embodiment, the protection layer 14 can be an optical protection gel. In addition, the method for forming the protection layer 14 is not particularly limited, and may be any coating processes known in the art, for example, spin coating, blade coating, inkjet coating, printing, roll coating, spray coating, etc.

As shown in FIG. 2D, a light absorbing material 15 is formed on the protection layer 14 to obtain the white light emitting diode of the present embodiment. Herein, the light absorbing material 15 may be formed by the method illustrated in Embodiment 1.

As shown in FIG. 2D, the white light emitting diode of the present embodiment comprises: a blue light emitting diode chip 11; a phosphor layer 13 disposed on the blue light emitting diode chip 11; and a light absorbing material 15 disposed on the phosphor layer 13, wherein the light absorbing material 15 is a yellow light absorbing material. In addition, the white light emitting diode of the present embodiment further comprises a protection layer 14 disposed on the phosphor layer 13, and the light absorbing material 15 is disposed on the protection layer 14.

One difference between the white light emitting diodes of the present embodiment and Embodiment 1 is that the phosphor layer 13 of the present embodiment is a thin film of phosphors, which is a thin film formed by phosphor particles 132. In the white light emitting diode of the present embodiment, the phosphor layer 13 is directly formed on the second surface 112 and the side surface 113 of the blue light emitting diode chip 11. In other words, the phosphor layer 13 is formed on the surfaces (including the second surface 112 and the side surface 113) of the blue light emitting diode chip 11 except for the first surface 111 disposed with the electrodes 12. In addition, the white light emitting diode of the present embodiment further comprises a protection layer 14 disposed on the surfaces of the phosphor layer 13 corresponding to the second surface 112 and the side surface 113. More specifically, in the present embodiment, the phosphor layer 13 is formed on the second surface 112 and the side surface 113 of the blue light emitting diode chip 11, and the protection layer 14 is used to protect the phosphor layer 13, so the protection layer 14 is formed on the surfaces of the phosphor layer 13 corresponding to the second surface 112 and the side surface 113.

In the present embodiment, the light absorbing material 15 is disposed on the protection layer 14 in a thin film, and the protection layer 14 is disposed between the phosphor layer 13 and the light absorbing material 15. Thus, the light emitting from the phosphor layer 13 can pass through the protection layer 14 and achieve to the light absorbing material 15, and the light absorbing material 15 can absorb the yellow light with undesired wavelength to improve the color gamut of the white light emitting diode.

In the present embodiment, the materials of the phosphor layer 13 and the light absorbing material 15 can be similar to those illustrated in Embodiment 1 and are not repeated again. In addition, in the present embodiment, the material of the electrodes 12 may comprise, but is not limited to, Cu, Al, Mo, W, Au, Cr, Ni, Pt, Ti, Cu alloy, Al alloy, Mo alloy, W alloy, Au alloy, Cr alloy, Ni alloy, Pt alloy, Ti alloy, or other suitable metal or metal alloy.

### Embodiment 3

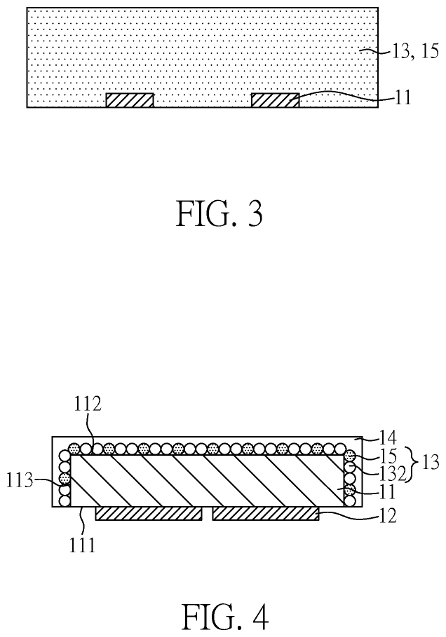

FIG. 3 is a cross-sectional view of a white light emitting diode according the present embodiment. The method for preparing the white light emitting diode of the present embodiment is similar to that illustrated in Embodiment 1, except for the following differences.

In the present embodiment, the light absorbing material 15 is disposed in the phosphor layer 13. More specifically, in the present embodiment, the phosphor layer 13 is a phosphor gel layer, which can be a layer formed by a gel containing the phosphors and the light absorbing material 15. Thus, the white light emitting diode of the present embodiment does not comprise the layer formed by the light absorbing material as shown in Embodiment 1.

### Embodiment 4

FIG. 4 is a cross-sectional view of a white light emitting diode of the present embodiment. The manufacturing method and the structure of the white light emitting diode of the present embodiment are similar to those shown in Embodiment 2, except for the following differences.

In the present embodiment, the light absorbing material 15 is disposed in the phosphor layer 13. More specifically, in the present embodiment, the phosphor layer 13 is a thin film of the phosphors, which can be a thin film constituted by the phosphor particles 132 and the light absorbing material 15. Thus, the light emitting diode of the present embodiment does not comprise the layer formed by the light absorbing material as shown in Embodiment 2.

### Embodiment 5

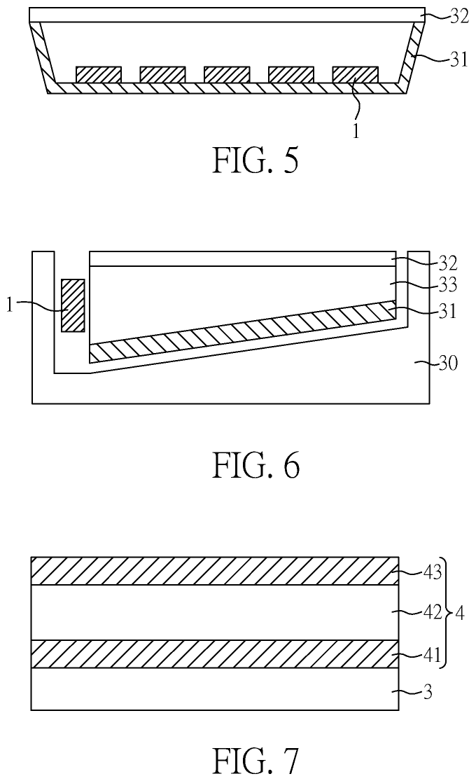

FIG. 5 is a cross-sectional view of a direct-light type backlight module according the present embodiment. As shown in FIG. 5, the backlight module of the present embodiment comprises: a reflecting film 31; an optical film 32 disposed on the reflecting film 31; and a white light emitting diode 1 disposed between the reflecting film 31 and the optical film 32. In the present embodiment, the white light emitting diode 1 can be any white light emitting diode shown in Embodiment 1 to Embodiment 4.

In the present embodiment, the reflecting film 31 may be used as a house for the backlight module. In addition, even not shown in the figure, the optical film 32 may comprise conventional films used in the backlight module, for example, a diffusion film, a prism sheet or a brightness enhancement film. However, the present disclosure is not limited thereto, and the constitution of the optical film 32 can be adjusted according to the need.

### Embodiment 6

FIG. 6 is a cross-sectional view of an edge-light type backlight module according the present embodiment. The backlight module of the present embodiment is similar to that shown in Embodiment 5, except for the following differences.

As shown in FIG. 6, the backlight module of the present embodiment further comprises a light guide plate 33 disposed between the reflecting film 31 and the optical film 32, and the white light emitting diode 1 is disposed at one side of the light guide plate 33. In addition, the backlight module of the present embodiment further comprises a house 30, and the reflecting film 31, the optical film 32, the light guide plate 33 and the white light emitting diode 1 are disposed in the containing space of the house 30.

### Embodiment 7

FIG. 7 is a cross-sectional view of a display device according to the present embodiment. As shown in FIG. 7, the display device of the present embodiment comprises: a backlight module 3; and a display panel 4 disposed on the backlight module 3. The backlight module 3 can be the backlight module shown in Embodiment 5 or Embodiment 6. In addition, the display panel 4 may comprise: a first substrate 41; a second substrate 43 opposite to the first substrate 41; and a display layer 42 disposed between the first substrate 41 and the second substrate 43. In the present embodiment, the display layer 42 is a liquid crystal layer.

In one aspect of the present embodiment, the first substrate 41 can be a thin film transistor substrate with thin film transistors (not shown in the figure) formed thereon, and the second substrate 43 can be a color filter substrate with a color filter layer (not shown in the figure) or a black matrix layer (not shown in the figure) formed thereon. In another aspect of the present embodiment, the color filter layer (not shown in the figure) may be disposed on the first substrate 41, and the first substrate 41 is a color filter on array (COA) substrate. In further aspect of the present embodiment, the black matrix layer (not shown in the figure) may be disposed on the first substrate 41, and the first substrate 41 is a black matrix on array (BOA) substrate.

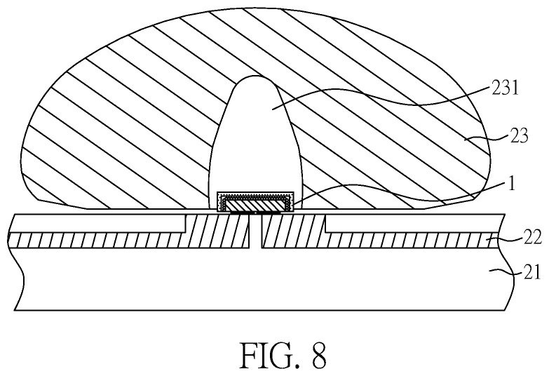

Test example FIG. 8 is a cross-sectional view of a testing unit used in Test example of the present disclosure. The testing unit used in the present test example comprises: a print circuit board 21 with a circuit 22 formed thereon; a white light emitting diode 1 shown in FIG. 2C or FIG. 2D, wherein the electrodes 12 (as shown in FIG. 2C or FIG. 2D) electrically connects to the circuit 22; and a diffusion lens 23 disposed on the print circuit board 21, wherein the white light emitting diode 1 shown in FIG. 2C or FIG. 2D is disposed in the cavity 231 of the diffusion lens 23. When the white light emitting diode 1 is the white light emitting diode shown in FIG. 2C, the obtained testing unit is the testing unit used in the comparative example of the present test example. When the white light emitting diode 1 is the white light emitting diode shown in FIG. 2D, the obtained testing unit is the testing unit used in the experimental example of the present test example.

Then, the tests units shown in FIG. 8 are used in the backlight module shown in FIG. 5, and applied to the display device shown in FIG. 7, wherein the first substrate 41 is a thin film transistor substrate and the second substrate 43 is a color filter substrate.

In the present test example, the phosphors used in the white light emitting diodes shown in FIG. 2C and FIG. 2D are phosphors mixing by red-emitting potassium fluoride silicon (KSF) phosphors and green-emitting beta-Sialon:Eu²⁺ nitroxide phosphors in a weight ratio of 2:1. The material of the protection layer 14 is an optical protection gel. In addition, the light absorbing material 15 of the white light emitting diode of the experimental example is triphenylmethane-based basic dye. Furthermore, the spectra obtained in the comparative example and the experimental example are detected by the LED integrating sphere, and the color gamut obtained in the comparative example and the experimental example are detected by the color analyzer.

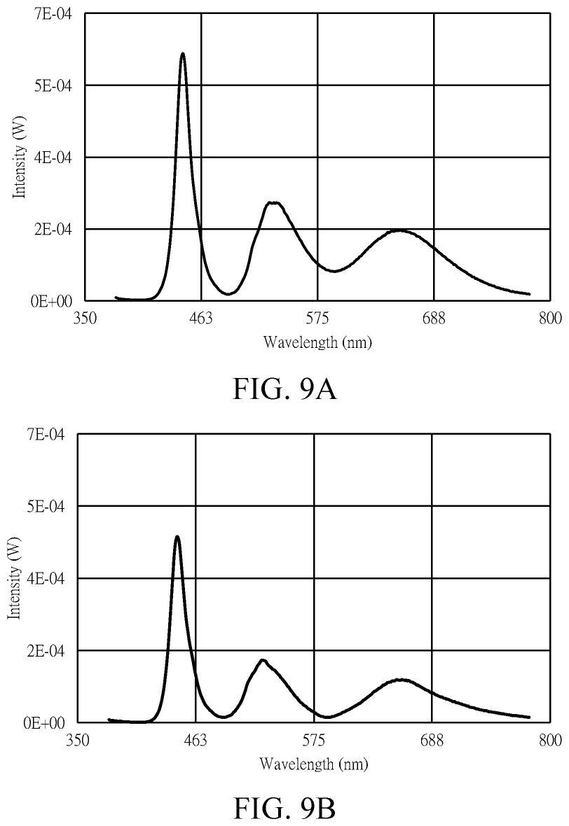

The spectra obtained in the comparative example and the experimental example are respectively shown in FIG. 9A and FIG. 9B. Compared to the white light emitting diode of the comparative example without using the yellow light absorbing material, the intensity of the light with undesired wavelengths ranging from 550 nm to 610 nm can be significant reduced in the white light emitting diode comprising the yellow light absorbing material of the experimental example. In addition, 74.4% NTSC can be obtained by using the testing unit of the comparative example, but 93.9% NTSC can be obtained by using the testing unit of the experimental example.

As mentioned above, when the white light emitting diode comprises the yellow light absorbing material, the yellow light absorbing material can effectively absorb the light with undesired wavelength in the yellow light range, and in particular can effectively absorb the light with undesired wavelength ranging from 550 nm to 610 nm. Thus, the intensity of the light having the wavelength in the aforesaid range can be significantly reduced, and therefore the color gamut of the white light emitting diode can be effectively improved.

The white light emitting diode of the present disclosure can be applied to a backlight module as a light source in any display device. The example of the display device may comprise, but is not limited to displays, mobile phones, laptops, video cameras, still cameras, music players, mobile navigators, or TV sets.

Although the present disclosure has been explained in relation to its embodiment, it is to be understood that many other possible modifications and variations can be made without departing from the spirit and scope of the disclosure as hereinafter claimed.

What is claimed is:

1. A white light emitting diode, comprising:
a blue light emitting diode chip;
a phosphor layer disposed on the blue light emitting diode chip; and
a light absorbing material disposed on the phosphor layer or in the phosphor layer, wherein the light absorbing material is a yellow light absorbing material.

2. The white light emitting diode of claim 1, wherein the yellow light absorbing material absorbs light having wavelength ranged from 550 nm to 610 nm.

3. The white light emitting diode of claim 1, wherein the yellow light absorbing material is triphenylmethane-based material, cobalt blue, cobalt violet or a combination thereof.

4. The white light emitting diode of claim 1, wherein the phosphor layer is a phosphor gel layer.

5. The white light emitting diode of claim 1, wherein the phosphor layer is a thin film of phosphors.

6. The white light emitting diode of claim 5, further comprising a protection layer disposed on the thin film of the phosphors, wherein the light absorbing material is disposed on the protection layer.

7. A backlight module, comprising:
a reflecting film;
an optical film disposed on the reflecting film; and
a white light emitting diode disposed between the reflecting film and the optical film and comprising:
a blue light emitting diode chip;
a phosphor layer disposed on the blue light emitting diode chip; and
a light absorbing material disposed on the phosphor layer or in the phosphor layer, wherein the light absorbing material is a yellow light absorbing material.

8. The backlight module of claim 7, wherein the yellow light absorbing material absorbs light having wavelength ranged from 550 nm to 610 nm.

9. The backlight module of claim 7, wherein the yellow light absorbing material is triphenylmethane-based material, cobalt blue, cobalt violet or a combination thereof.

10. The backlight module of claim 7, wherein the phosphor layer is a phosphor gel layer.

11. The backlight module of claim 7, wherein the phosphor layer is a thin film of phosphors.

12. The backlight module of claim 11, wherein the white light emitting diode further comprises a protection layer disposed on the thin film of the phosphors, and the light absorbing material is disposed on the protection layer.

13. A display device, comprising:
a backlight module; and
a display panel disposed on the backlight module;
wherein the backlight module comprises: a reflecting film; an optical film disposed on the reflecting film; and a white light emitting diode disposed between the reflecting film and the optical film and comprising:
a blue light emitting diode chip;
a phosphor layer disposed on the blue light emitting diode chip; and
a light absorbing material disposed on the phosphor layer or in the phosphor layer, wherein the light absorbing material is a yellow light absorbing material.

14. The display device of claim 13, wherein the yellow light absorbing material absorbs light having wavelength ranged from 550 nm to 610 nm.

15. The display device of claim 13, wherein the yellow light absorbing material is triphenylmethane-based material, cobalt blue, cobalt violet or a combination thereof.

16. The display device of claim 13, wherein the phosphor layer is a phosphor gel layer.

17. The display device of claim 13, wherein the phosphor layer is a thin film of phosphors.

18. The display device of claim 17, wherein the white light emitting diode further comprises a protection layer disposed on the thin film of the phosphors, and the light absorbing material is disposed on the protection layer.
